(19) United States
(12) Patent Application Publication
(10) Pub. No.: US 2005/0285263 A1
(43) Pub. Date: Dec. 29, 2005

(54) Semiconductor device

(75) Inventor: Masahiro Ogawa, Osaka (JP)

Correspondence Address: STEPTOE & JOHNSON LLP, 1330 CONNECTICUT AVENUE, N.W., WASHINGTON, DC, 20036, US

(73) Assignee: MATSUSHITA ELECTRIC INDUSTRIAL CO., LTD., Osaka (JP)

(21) Appl. No.: 11/153,412

(22) Filed: Jun. 16, 2005

(30) Foreign Application Priority Data
Jun. 29, 2004 (JP) 2004-190582

(51) Int. Cl. H01L 23/34

(52) U.S. Cl. 257/723

(57) ABSTRACT

A semiconductor device includes a substrate (1) where a plurality of wiring patterns are formed, a first semiconductor chip (3) mounted on one surface of the substrate (1), a spacer (4) which is mounted on the substrate (1) and adjacent to the first semiconductor chip (3), and a second semiconductor chip (6) mounted on one surface of the first semiconductor chip (3) and one surface of the spacer (4). The first semiconductor chip (3) composed of two or more elements and the spacer (4), on which pads (21) used for thermal dissipation and semiconductor elements (22) are mounted, are simultaneously formed in the diffusion process of a semiconductor wafer.

### FIELD OF THE INVENTION

The present invention relates to a multilayer semiconductor device.

### BACKGROUND OF THE INVENTION

In recent years, digital camera systems, digital video cameras, and mobile tools such as camera phones have decreased in size and weight and achieved higher image quality. Therefore, components such as semiconductor chips constituting these systems are packaged in a smaller area and thus conventional chips arranged side by side and chips mounted on both surfaces cannot be packaged. While system operations become faster with higher functionality, product cycles are shortened. Thus, it is necessary to construct systems in a short time.

Systems are configured as black boxes and each system is constituted of a single chip to differentiate a product from others. For this reason, it is necessary to mount two or more chips in a package. Further, it is necessary to reduce the overall development costs of products. Moreover, it is necessary to mount different kinds of process products to produce chips which are difficult to obtain in system-on-chip configurations.

In order to solve these problems, semiconductor chips are stacked in some configurations. Such a semiconductor device is disclosed in JP 2002-373968A. In this semi conductor device, semiconductor chips are stacked with a spacer having substantially the same thickness as the semiconductor chips.

However, in this conventional semiconductor device, a semiconductor chip is stacked over a mounted semiconductor chip and thus the size of the stacked chip considerably affects the stacking method of the semiconductor chips.

For example, when semiconductor chips are stacked, the semiconductor chips and spacer to be mounted have to be positioned separately. Therefore, two-dimensional and three-dimensional adjustments are necessary and result in low productivity.

### DISCLOSURE OF THE INVENTION

It is an object of the present invention to provide a semiconductor device of high productivity.

A semiconductor device of the present invention comprises a substrate where a plurality of wiring patterns are formed, a first semiconductor chip mounted on one surface of the substrate, a spacer which is mounted on the substrate and adjacent to the first semiconductor chip, and a second semiconductor chip mounted on one surface of the first semiconductor chip and one surface of the spacer. The spacer is formed concurrently with the first semiconductor chip in the diffusion process of a semiconductor wafer.

### BRIEF DESCRIPTION OF THE DRAWINGS

FIG. 1 is a side view showing a semiconductor device according to Embodiment 1 of the present invention;

FIG. 2 is a perspective view showing the semiconductor device;

FIG. 3 is a diagram showing a first semiconductor chip and a spacer of the semiconductor device;

FIG. 4 is an internal structural diagram showing the spacer of the semiconductor device;

FIG. 5 is an internal structural diagram showing the connection relationship of the spacer of the semiconductor device;

FIG. 6A is a diagram showing the spacer of the semiconductor device, the first semiconductor chip, and the thickness of the spacer before a backgrinding process;

FIG. 6B is a diagram showing the spacer of the semiconductor device, the first semiconductor chip, and the thickness of the spacer after the backgrinding process; and

FIG. 7 is a perspective view showing a semiconductor device according to Embodiment 2 of the present invention.

### DESCRIPTION OF THE EMBODIMENTS

The following will describe semiconductor devices according to embodiments of the present invention with reference to the accompanying drawings.

### Embodiment 1

As shown in FIGS. 1 and 2, a semiconductor device according to Embodiment 1 of the present invention comprises a substrate 1, external electrodes 2, a first semiconductor chip 3, a spacer 4, an insulating film 5, a second semiconductor chip 6, a first pad 7A, a second pad 7B, a third pad 7C, a fourth pad 7D, a first electrode 8A, a second electrode 8B, a third electrode 8C, a fourth electrode 8D, a first wire 9A, a second wire 9B, a third wire 9C, and a fourth wire 9D.

The substrate 1 s composed of an inorganic composite (e.g., a ceramic substrate and a glass substrate) and has a plurality of wiring patterns formed on one surface (the top surface in the vertical direction). The substrate 1 is formed with a single layer.

The external electrodes 2 are disposed on the other surface (the undersurface in the vertical direction) of the substrate 1 and are connected to other components.

The first semiconductor chip 3 is mounted on one surface (top surface) of the substrate 1.

The spacer 4 is mounted on the substrate 1 and adjacent to the first semiconductor chip 3.

The second semiconductor chip 6 is mounted on one surface of the first semiconductor chip 3 and one surface of the spacer 4 via the insulating film 5. The first semiconductor chip 3 and the second semiconductor chip 6 are insulated from each other by the insulating film 5.

The first pad 7A and the second pad 7B are input/output electrodes used for thermal dissipation and disposed on one side of the first semiconductor chip 3 (the opposite side from the spacer 4).

The third pad 7C and the fourth pad 7D are input/output electrodes used for thermal dissipation and disposed on one side of the second semiconductor chip 6.

The first electrode 8A, the second electrode 8B, the third electrode 8C, and the fourth electrode 8D are disposed on one side of the substrate 1.

The first wire 9A connects the first pad 7A and the first electrode 8A.

The second wire 9B connects the second pad 7B and the second electrode 8B.

The third wire 9C connects the third pad 7C and the third electrode 8C.

The fourth wire 9D connects the fourth pad 7D and the fourth electrode 8D.

The first semiconductor chip 3 and the spacer 4 in the semiconductor device described above are integrally formed in advance before the assembling of the semiconductor device. The following will describe a forming method with reference to the accompanying drawings.

First, in the configuration of the semiconductor device, formulas (1) to (5) below are applied to the first semiconductor chip 3, the spacer 4, and the second semiconductor chip 6.
The height of the first semiconductor chip 3=the height of the spacer 4 (1)
{The length of the first semiconductor chip 3 in direction X in which the first semiconductor chip 3 and the spacer 4 are arranged (hereinafter, referred to as horizontal direction X)+the length of the spacer 4 in the horizontal direction X}>the length of the second semiconductor chip 6 in the horizontal direction X (2)
{The length of the first semiconductor chip 3 in direction Y perpendicular to the horizontal direction X (hereinafter, referred to as depth direction Y) in a horizontal component+the length of the spacer 4 in the depth direction Y}>the length of the second semiconductor chip 6 in the depth direction Y (3)
The length of the first semiconductor chip 3 in the horizontal direction X=the maximum length of the spacer 4 in the horizontal direction X (4)
The length of the first semiconductor chip 3 in the depth direction Y=the maximum length of the spacer 4 in the depth direction Y (5)

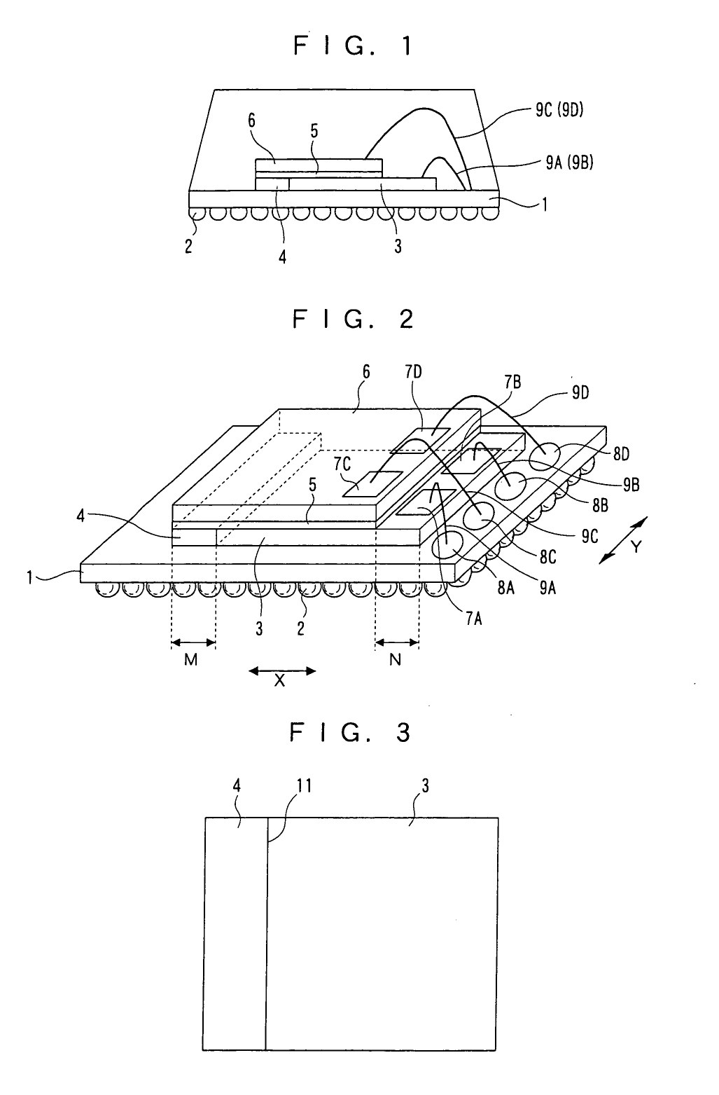

The formulas (1) to (5) are applied to determine the dimensions of the first semiconductor chip 3 and the spacer 4. As shown in FIG. 3, the first semiconductor chip 3 composed of two or more elements and the spacer 4 adjacent to the first semiconductor chip 3 are simultaneously formed in the diffusion process of the first semiconductor chip 3 and a semiconductor wafer. Further, the first semiconductor chip 3 and the spacer 4 are adjacent to each other via a scribe lane 11 which physically separates the first semiconductor chip 3 and the spacer 4 according to the circumstances. The first semiconductor chip 3 and the spacer 4 are not electrically connected to each other. The wiring patterns of the first semiconductor chip 3 and the spacer 4 are simultaneously formed by a photomask in the diffusion process.

As shown in FIG. 2, a width M of the spacer 4 in the horizontal direction X is adjusted according to the size of the stacked second semiconductor chip 6. In other words, the width M of the spacer 4 in the horizontal direction X is adjusted beforehand to obtain a width N of the wire bonding portion of the first semiconductor chip 3. Thus, the widths (lengths) of the first semiconductor chip 3, the spacer 4, and the second semiconductor chip 6 in the horizontal direction X are determined. Then, according to the determined widths (lengths), the first semiconductor chip 3 and the spacer 4 are fabricated in the diffusion process.

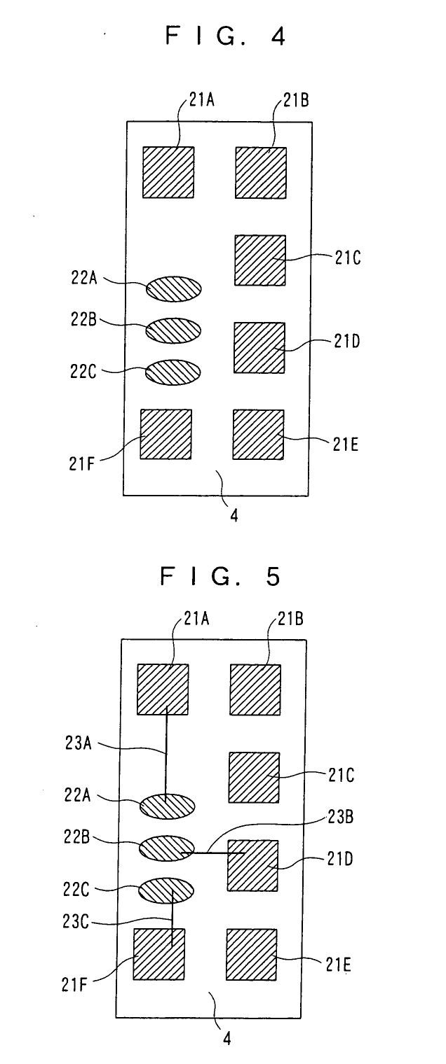

Referring to FIG. 4, the configuration of the spacer 4 will be discussed below.

As shown in FIG. 4, on the spacer 4, six (two or more) pads 21A, 21B, 21C, 21D, 21E, and 21F are formed and three (two or more) semiconductor elements 22A, 22B, and 22C such as a capacitor and a resistor are formed. The pads are input/output electrodes used for thermal dissipation. The pads 21 and the semiconductor elements 22 are formed by diffusion concurrently with the first semiconductor chip 3 in the diffusion process. Further, control can be performed in the diffusion process to set the resistance of a resistor serving as the semiconductor element 22 and the capacitance of a capacitor at required values. Moreover, the number of semiconductor elements 22 can be freely increased or reduced when necessary. The semiconductor elements 22 can be connected to the pads 21 of the spacer 4 when necessary.

Referring to FIG. 5, the following will discuss a connection example of the pads 21 and the semiconductor elements 22 which serve as the capacitor or the resistor in the spacer 4.

The pad 21A and the semiconductor element 22A are connected to each other via a wire 23A. The pad 21D and the semiconductor element 22B are connected to each other via a wire 23B. The pad 21F and the semiconductor element 22C are connected to each other via a wire 23C.

Hence, the characteristics of the semiconductor elements 22A, 22B, and 22C connected to the pads 21A, 21D, and 21F are made effective via the pads 21. The wires 23 are also formed arbitrarily in the diffusion process. The provision of the two or more pads 21 on the spacer 4 enables thermal dissipation.

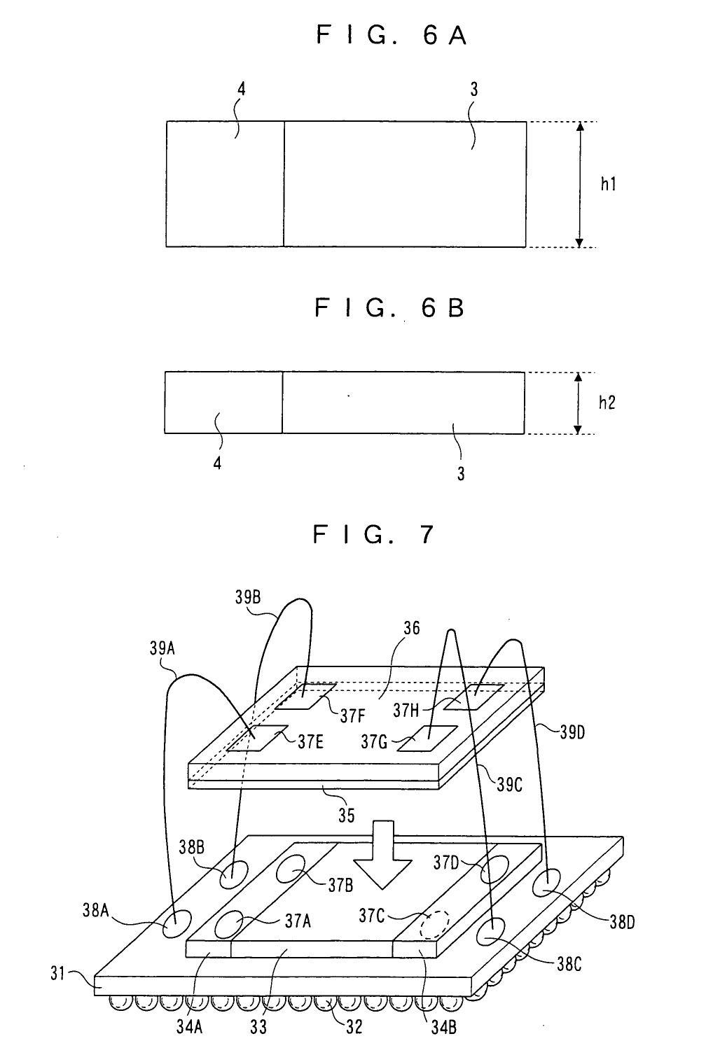

Referring to FIG. 6, the following will discuss a backgrinding process after the first semiconductor chip 3 and the spacer 4 are fabricated in the diffusion process.

(Step 1)

FIG. 6A shows the completion of the diffusion process of the first semiconductor chip 3 and the spacer 4. Reference character h1 denotes the thickness of the first semiconductor chip 3 and the spacer 4. The first semiconductor chip 3 and the spacer 4 are not electrically connected to each other.

(Step 2)

In order to stack the second semiconductor chip 6, the first semiconductor chip 3 and the spacer 4 with the thickness of h1 in the state of step 1 are ground to a desired thickness by a backgrinder (not shown). Then, as shown in FIG. 6B, the first semiconductor chip 3 and the spacer 4 have a thickness of h2. In this case, the relationship of h1>h2 is established.

With the scribe lane 11 shown in FIG. 3, the spacer 4 is so formed as to be physically separated from the first semiconductor chip 3. Thus, after the relationship h1>h2 is established, the first semiconductor chip 3 and the spacer 4 may be separated from each other. The separated spacer 4 may be used after rotated (flipped) by 180° with the first semiconductor chip 3 when necessary. In this case, the relationship between the thicknesses of the first semiconductor chip 3 and the spacer 4 is expressed by the formula below:
The thickness of the first semiconductor chip 3=the thickness of the spacer 4=h2 (6)

The first semiconductor chip 3 and the spacer 4 are simultaneously worked to have the same thickness. Hence, after the first semiconductor chip 3 and the spacer 4 are cut using the scribe lane 11, even when the first semiconductor chip 3 and the spacer 4 are rotated by 180° about the axis along the horizontal direction X or the width direction Y, that is, even when the first semiconductor chip 3 and the spacer 4 are flipped and used, the height remains completely the same.

Therefore, in the backgrinding process after the diffusion process, the thickness of the spacer 4 is equal to that of the first semiconductor chip 3.

As described above, the first semiconductor chip 3 composed of two or more elements and the spacer 4, on which the pads 21 used for thermal dissipation and the semiconductor elements 22 such as a capacitor and a resistor are mounted, are integrally formed at the same time in the diffusion process of the first semiconductor chip and the semiconductor wafer. Therefore, in the backgrinding process after the diffusion process, the thickness of the spacer 4 is equal to that of the first semiconductor chip 3.

The dimensions of the first semiconductor chip 3 and the spacer 4 are determined beforehand, so that the first semiconductor chip 3 and the spacer 4 can have the optimum chip size. The size can be determined to have the maximum number of packaged first semiconductor chips 3 and spacers 4 in the diffusion process of the semiconductor wafer, so that the present embodiment is quite effective for a two-layer semiconductor device.

The semiconductor device is effective in the presence of the pads 7A and 7B which are wire-bonded only to one side of the first semiconductor chip 3.

A constraint of the two-layer semiconductor device is that the relationship between the first semiconductor chip 3 and the second semiconductor chip 6 becomes effective in the following case:
The size of the first semiconductor chip 3≦the size of the second semiconductor chip 6 (7)

### Embodiment 2

Referring to FIG. 7, the following will describe a semiconductor device using a first semiconductor chip and a spacer according to Embodiment 2 of the present invention.

As shown in FIG. 7, the semiconductor device of Embodiment 2 comprises a substrate 31, external electrodes 32, a first semiconductor chip 33, a first spacer 34A, a second spacer 34B, an insulating film 35, a second semiconductor chip 36, a first pad 37A, a second pad 37B, a third pad 37C, a fourth pad 37D, a fifth pad 37E, a sixth pad 37F, a seventh pad 37G, an eighth pad 37H, a first electrode 38A, a second electrode 38B, a third electrode 38C, a fourth electrode 38D, a first wire 39A, a second wire 39B, a third wire 39C, and a fourth wire 39D.

The substrate 31 is composed of an inorganic composite (e.g., a ceramic substrate and a glass substrate) and has a plurality of wiring patterns formed on one surface (the top surface in the vertical direction). The substrate 31 is formed with a single layer.

The external electrodes 32 are formed on the other surface (the undersurface in the vertical direction) of the substrate 31 and are connected to other components.

The first semiconductor chip 33 is mounted on one surface (top surface) of the substrate 31.

The first spacer 34A and the second spacer 34B are mounted on the substrate 31 and adjacent to both sides of the first semiconductor chip 33.

The second semiconductor chip 36 is mounted on one surface of each of the first semiconductor chip 33 and the spacers 34A and 34B via the insulating film 35. The first semiconductor chip 33 and the second semiconductor chip 36 are insulated from each other by the insulating film 35.

The first pad 37A and the second pad 37B are disposed on the first spacer 34A and used for thermal dissipation.

The third pad 37C and the fourth pad 37D are disposed on the second spacer 34B and used for thermal dissipation.

The fifth pad 37E and the sixth pad 37F are input/output electrodes used for thermal dissipation and disposed on one side (first spacer side) of the second semiconductor chip 36.

The seventh pad 37G and the eighth pad 37H are input/output electrodes used for thermal dissipation and disposed on the other side (second spacer side) of the second semiconductor chip 36.

The first electrode 38A and the second electrode 38B are disposed on one side of the substrate 31.

The third electrode 38C and the fourth electrode 38D are disposed on the other side of the substrate 31.

The first wire 39A connects the fifth pad 37E and the first electrode 38A.

The second wire 39B connects the sixth pad 37F and the second electrode 38B.

The third wire 39C connects the seventh pad 37G and the third electrode 38C.

The fourth wire 39D connects the eighth pad 37H and the fourth electrode 38D.

The following will discuss a method of integrally forming the first semiconductor chip 33 and the spacers 34A and 34B of the semiconductor device simultaneously according to Embodiment 2.

Like the semiconductor device of Embodiment 1, the first spacer 34A and the second spacers 34B are adjacent to both sides of the first semiconductor chip 33 composed of two or more elements. The dimensions (particularly the width in the horizontal direction) of the first semiconductor chip 33, the first spacer 34A, and the second spacer 34B are determined beforehand and the first semiconductor chip 33 and the spacers 34A and 34B are simultaneously fabricated in a diffusion process. Then, in a backgrinding process after the diffusion process, the first semiconductor chip 33, the first spacer 34A, and the second spacer 34B are formed to have the same thickness (e.g., h2). The first semiconductor chip 33 is physically connected to the first spacer 34A and the second spacer 34B directly but is not electrically connected to the spacers 34A and 34B directly.

The first pad 37A, the second pad 37B, the third pad 37C, and the fourth pad 37D of the first spacer 34A and the second spacer 34B are electrically connected to the substrate 31 while the first semiconductor chip 33, to which the first spacer 34A and the second spacer 34B are connected, is rotated by 180° about the axis along the horizontal direction X or the width direction Y, that is, the first semiconductor chip 33 is flipped over. Thus, the heat of the first semiconductor chip 33 is released through the first spacer 34A and the second spacer 34B.

At least one of the first spacer 34A and the second spacer 34B formed on both sides of the first semiconductor chip 33 maybe separated from the first semiconductor chip 33 and rotated by 180° about the axis along the horizontal direction X or the width direction Y, that is, one of the first spacer 34A and the second spacer 34B may be flipped over and disposed on the substrate 31.

In this way, the overall dimensions of the first semiconductor chip 33, the first spacer 34A, and the second spacer 34B are determined beforehand, so that the first semiconductor chip 33 and the spacers 34A and 34B can have the optimum chip size. The size can be determined to have the maximum number of packaged first semiconductor chips 33 and spacers 34A and 34B in the diffusion process of the semiconductor wafer, so that the present embodiment is quite effective for a two-layer semiconductor device. This technique is effective for rotating the second semiconductor chip 36 to be stacked by 180° and transmitting heat to the substrate 31.

Semiconductor elements required for the spacers 34A and 34B are set at desired values during diffusion, so that the spacers can act as external components. A connection is made to the first semiconductor chip 33 on the substrate 31.

As described above, according to Embodiments 1 and 2, the first semiconductor chip 3 (33) composed of two or more elements and the spacer 4 (first spacer 34A and second spacer 34B), on which the pads 21 used for thermal dissipation and the semiconductor elements 22 such as a capacitor and a resistor are mounted, are simultaneously formed in the diffusion process of the first semiconductor chip 3 (33) and the semiconductor wafer. Thus, when the second semiconductor chip 6 (36) is stacked, it is possible to eliminate the two-dimensional and three-dimensional positioning of the first semiconductor chip 3 (33) and the spacer 4 (first spacer 34A and second spacer 34B) and eliminate precise working on dimensions such as the height and width of components. Since it is possible to quickly stack the second semiconductor chip 6 (36) with ease, thereby increasing the productivity of the semiconductor device during assembling.

According to Embodiments 1 and 2, the first semiconductor chip 3 (33) and the spacer 4 (first spacer 34A and second spacer 34B) can have the optimum chip size. Moreover, the size can be determined to have the maximum number of packaged first semiconductor chips 3 (33) and spacers 4 (first spacer 34A and second spacer 34B) in the diffusion process of the semiconductor wafer, so that the present embodiment is quite effective for a two-layer semiconductor device.

In Embodiments 1 and 2, the substrate 1 (31) is composed of an inorganic composite (e.g., a ceramic substrate and a glass substrate). The substrate 1 (31) may be composed of an organic composite (e.g., a polyimide substrate) or an inorganic-organic composite.

In Embodiments 1 and 2, the substrate 1 (31) is formed with a single layer. The substrate 1 (31) may have two or more layers.

Further, in Embodiments 1 and 2, the substrate 1 (31) is used which has two or more wiring patterns formed on one surface. A substrate having two or more wiring patterns on both surfaces may be used.

Moreover, in Embodiments 1 and 2, the electrodes of the first semiconductor chip 3 (33) face the top surface of the substrate 1 (31). The electrodes may face the undersurface of the substrate 1 (31).

1. A multilayer semiconductor device, comprising:
a substrate having a plurality of wiring patterns formed thereon,
a first semiconductor chip mounted on one surface of the substrate,
a spacer mounted on the substrate and arranged to be adjacent to the first semiconductor chip, and
a second semiconductor chip mounted on one surface of the first semiconductor chip and one surface of the spacer, wherein the spacer is formed concurrently with the first semiconductor chip in a diffusion process of a semiconductor wafer.

2. The semiconductor device according to claim 1, wherein a width of the spacer in a horizontal direction, in which the first semiconductor chip and the spacer are arranged, is adjusted according to a size of the second semiconductor chip to be stacked.

3. The semiconductor device according to claim 1, wherein the spacer has a plurality of pads used for thermal dissipation.

4. The semiconductor device according to claim 3, wherein the spacer has a plurality of semiconductor elements connected to the pads.

5. The semiconductor device according to claim 1, wherein the spacer is equal in thickness to the first semiconductor chip.

6. The semiconductor device according to claim 1, wherein the spacer is so formed as to be physically separated from the first semiconductor chip.

7. The semiconductor device according to claim 1, wherein the spacers are formed on both sides of the first semiconductor chip.

8. The semiconductor device according to claim 7, wherein at least one of the spacers formed on both sides of the first semiconductor chip is physically separated from the first semiconductor chip, rotated by 180° about an axis along a horizontal direction or a direction perpendicular to the horizontal direction, and disposed on the substrate.
